(19) United States
(12) Patent Application Publication
(10) Pub. No.: US 2010/0238784 A1
(43) Pub. Date: Sep. 23, 2010

(54) Multiwavelength semiconductor laser and optical recording/reproducing device

(75) Inventor: Yoshihiko Takahashi, Miyagi (JP)

Correspondence Address: RADER FISHMAN & GRAUER PLLC, LION BUILDING, 1233 20TH STREET N.W., SUITE 501, WASHINGTON, DC, 20036, US

(73) Assignee: SONY CORPORATION, Tokyo (JP)

(21) Appl. No.: 12/656,386

(22) Filed: Jan. 28, 2010

(30) Foreign Application Priority Data
Mar. 18, 2009 (JP) 2009-066842

(51) Int. Cl. G11B 7/00; H01S 5/028

(52) U.S. Cl. 369/121; 372/49.01; G9B/7

(57) ABSTRACT

The present invention provides a multiwavelength semiconductor laser capable of easily setting reflectance in a predetermined range at different oscillation wavelengths on a main emission edge face side. The multiwavelength semiconductor laser includes a plurality of semiconductor light emission parts of an edge emitting type having different oscillation wavelengths, and a reflection film provided commonly for main emission edge faces of the semiconductor light emission parts. The reflection film includes, in order from the semiconductor light emission parts, a first dielectric film (refractive index n1), a second dielectric film (refractive index n2), and a third dielectric film (refractive index n3), and the refractive indexes n1, n2, and n3 satisfy the relation of n3<n1<n2.

### BACKGROUND OF THE INVENTION

1. Field of the Invention

The present invention relates to a multiwavelength semiconductor laser having a plurality of edge-emitting-type semiconductor light emitting parts having different emission wavelengths and to an optical recording/reproducing device using the same.

2. Description of the Related Art

With the standard and kind of an optical recording medium becoming diversified, optical recording/reproducing devices capable of recording/reproducing information in a wavelength band corresponding to a plurality of optical recording media are widely used. In the optical recording/reproducing device, a multiwavelength semiconductor laser of the edge emitting type is used as each of an optical pickup light source for recording and an optical pickup for reproduction. Concretely, there is an optical recording/reproducing device capable of recording/reproducing information in a 780 nm wavelength band and a 650 nm wavelength band in correspondence with both of a CD (Compact Disc) and a DVD (Digital Video Disc or Digital Versatile Disc). In an optical recording/reproducing device for CD and DVD, as an optical pickup light source for recording and reproduction, a 2-wavelength semiconductor laser having oscillation wavelengths in the 650 nm band and the 780 nm band is used.

A multiwavelength semiconductor laser has a monolithic structure in which a plurality of semiconductor laser elements having different oscillation wavelengths are mounted on a single semiconductor chip. Each semiconductor laser element has a semiconductor light emission part of the edge emitting type and a reflection film provided on each of a main emission edge face (front edge face) and a rear edge face. The reflectance of the reflection films is low on the main emission edge face side and is high on the rear edge face side. Each semiconductor laser element has a resonator structure that makes light emitted from the semiconductor light emission part resonate between the pair of reflection films (the low reflection film and the high reflection film). By the resonator structure, the resonated light is emitted as a laser beam from the side of the low-reflection film to the outside.

In such a multiwavelength semiconductor laser, when reflection films of different kinds corresponding to the oscillation wavelengths are provided in each semiconductor laser element, the process of forming the reflection films becomes complicated. Consequently, it is examined to provide a reflection film commonly used by a plurality of semiconductor laser elements.

For example, in Japanese Unexamined Patent Application Publication No. 2001-257413, a reflection film (low-reflection film) on the main emission edge film side is made of one kind of material, and its optical film thickness is set to the integral multiple of ¼ of average wavelength of the oscillation wavelengths. Concretely, in a 2-wavelength semiconductor laser having the oscillation wavelength of 650 nm band and the 780 nm band, the optical film thickness of an alumina film on the emission edge face side is set to the integral multiple of ¼ of the average value of about 715 nm of the oscillation wavelengths.

In a multiwavelength semiconductor laser of Japanese Unexamined Patent Application Publication No. 2004-327678, by providing a reflection film (low-reflection film) made of three dielectric films with the same thickness commonly to the side of a main emission edge face of semiconductor laser elements, the reflectance in the edge face at oscillation wavelengths is set to 15% or less. Concretely, in a 2-wavelenth semiconductor laser whose oscillation wavelengths are in the 650 nm band and the 780 nm band, by selecting materials of the dielectric films whose reflectances have a predetermined relation, the low-reflectance film is formed.

### SUMMARY OF THE INVENTION

In the techniques of the above-mentioned publications, however, it is difficult to set the reflection film on the main emission edge face side to desired reflectance. Concretely, in Japanese Unexamined Patent Application Publication No. 2001-257413, the optical film thickness of the low-reflection film made of one kind of material is set on the basis of the average wavelength of the oscillation wavelengths, so that variations in the reflectance at the different oscillation wavelengths tend to be large. Consequently, to obtain the edge face reflectance adapted to the oscillation wavelengths, the thickness of the low-reflection film is limited to a narrow range, and it is difficult to form a low-reflection film having predetermined reflectance without variations in multiwavelength semiconductor lasers. Although the technique of the Japanese Unexamined Patent Application Publication No. 2004-327678 is suitable to set the reflectance on the emission edge face side of each oscillation wavelength to 15% or less, it is not easy to form a low-reflection film having reflectance higher than that.

It is desirable to provide a multiwavelength semiconductor laser capable of easily setting reflectances at different oscillation wavelengths in a predetermined range on a main emission edge face side and an optical recording/reproducing device having the same.

A multiwavelength semiconductor laser according to an embodiment of the present invention includes: a plurality of semiconductor light emission parts of an edge emitting type having different oscillation wavelengths; and a reflection film provided commonly for main emission edge faces of the semiconductor light emission parts. The reflection film includes, in order from the semiconductor light emission parts, a first dielectric film (refractive index n1), a second dielectric film (refractive index n2), and a third dielectric film (refractive index n3), and the refractive indexes n1, n2, and n3 satisfy the relation of n3<n1<n2. An optical recording/reproducing device according to an embodiment of the invention has the above-mentioned multiwavelength semiconductor laser as a light source for reproduction.

In the multiwavelength semiconductor laser according to an embodiment of the present invention, the reflection film provided commonly for the main emission edge faces of the plurality of semiconductor light emission parts has, in order from the semiconductor light emission part side, the first dielectric film, the second dielectric film, and the third dielectric film, and the refractive indexes n1, n2, and n3 of the first, second, and third dielectric film satisfy the above-described relation. With the configuration, as compared with the case where the reflection film is formed by a single dielectric film, the case where the refractive indexes n1, n2, and n3 do not satisfy the relation such as the case where the relation of n1=n3<n2 is satisfied, and the like, changes in the reflectances at the oscillation wavelengths with respect to changes in the optical film thicknesses of the first to third dielectric films become gentler. That is, the permissible range of each of the optical film thicknesses of the dielectric films, in which predetermined reflectance is obtained at each oscillation wavelength is widened. Moreover, the reflectance of the reflection film may be also easily set to a range higher than 15% such as the range of 25% to 35% both inclusive. Therefore, in the optical recording/reproducing device using the multiwavelength semiconductor laser according to an embodiment of the invention, the multiwavelength semiconductor laser may be also excellently used as a light source for reproduction which is set to an output lower than that of the light source on the recording side.

In the multiwavelength semiconductor laser according to an embodiment of the invention, the reflection film provided commonly for the main emission edge faces of the plurality of semiconductor light emission parts includes the first, second, and third dielectric films having the above-described relation of refractive indexes. Consequently, on the main emission edge face side, the reflectances at the oscillation wavelengths are easily set in a predetermined range. Therefore, since the output of the light source is set in a proper range, the optical recording/reproducing device using the multiwavelength semiconductor laser according to an embodiment of the invention as the light source for reproduction reproduces information excellently.

Other and further objects, features and advantages of the invention will appear more fully from the following description.

### BRIEF DESCRIPTION OF THE DRAWINGS

FIG. 1 is a schematic diagram illustrating a plane configuration of a multiwavelength semiconductor laser according to an embodiment of the present invention.

FIG. 2 is a characteristic diagram illustrating the relation between the optical film thickness and reflectance in a low-reflection film of experimental example 1-1.

FIG. 3 is a characteristic diagram illustrating the relation between the optical film thickness and reflectance in a low-reflection film of experimental example 1-2.

FIG. 4 is a characteristic diagram illustrating the relation between the optical film thickness and reflectance in a low-reflection film of experimental example 1-3.

FIG. 5 is a characteristic diagram illustrating the relation between the optical film thickness and reflectance in a low-reflection film of experimental example 1-4.

FIG. 6 is a characteristic diagram illustrating the relation between the optical film thickness and reflectance in a low-reflection film of experimental example 1-5.

FIG. 7 is a characteristic diagram illustrating the relation between the optical film thickness and reflectance in a low-reflection film of experimental example 1-6.

FIG. 8 is a characteristic diagram illustrating the relation between the optical film thickness and reflectance in a low-reflection film of experimental example 1-7.

FIG. 9 is a characteristic diagram illustrating the relation between the optical film thickness and reflectance in a low-reflection film of experimental example 1-8.

FIG. 10 is a characteristic diagram illustrating the relation between the optical film thickness and reflectance in a low-reflection film of experimental example 1-9.

FIG. 11 is a characteristic diagram illustrating the relation between the optical film thickness and reflectance in a low-reflection film of experimental example 1-10.

FIG. 12 is a characteristic diagram illustrating the relation between the optical film thickness and reflectance in a low-reflection film of experimental example 1-11.

FIG. 13 is a characteristic diagram illustrating the relation between the optical film thickness and reflectance in a low-reflection film of experimental example 1-12.

FIG. 14 is a characteristic diagram illustrating the relation between the optical film thickness and reflectance in a low-reflection film of experimental example 1-13.

FIG. 15 is a characteristic diagram illustrating the relation between the optical wavelength and reflectance in low-reflection films of experimental examples 2-1 and 2-2.

### DETAILED DESCRIPTION OF THE PREFERRED EMBODIMENTS

Embodiments of the present invention will be described in detail below with reference to the drawings. The description will be given in the following order.

1. Configuration of Multiwavelength Semiconductor Laser (Example of Two-Wavelength Semiconductor Laser)

2. Method of manufacturing multiwavelength semiconductor laser

1. Configuration Example of Multiwavelength Semiconductor Laser (Example of Two-Wavelength Semiconductor Laser)

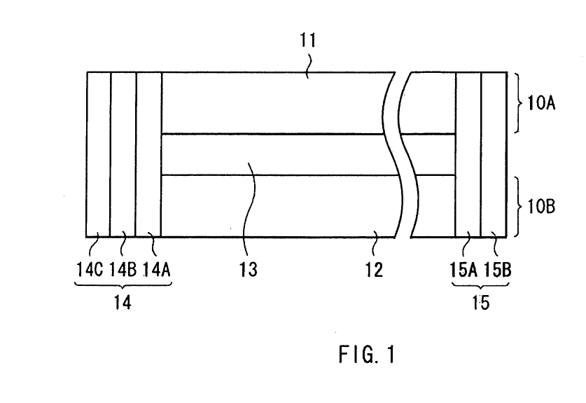

FIG. 1 schematically illustrates a plane configuration of a multiwavelength semiconductor laser according to an embodiment of the present invention. The multiwavelength semiconductor laser of the embodiment is used in, for example, an optical recording/reproducing device or the like and has a monolithic structure formed by semiconductor laser elements 10A and 10B of the edge emitting type having different oscillation wavelengths. That is, the multiwavelength semiconductor laser of the embodiment is a two-wavelength semiconductor laser. In the embodiment, the oscillation wavelengths of the semiconductor laser element 10A is set to 650 nm band, and that of the semiconductor laser element 10B is set to 780 nm wavelength band. The “650 nm wavelength band” is a wavelength band of 640 nm to 670 nm both inclusive, and the “780 nm wavelength band” is a wavelength band of 770 nm to 800 nm both inclusive.

The semiconductor laser element 10A has a first light emission part 11, and the semiconductor laser element 10B has a second light emission part 12. A low-reflection film 14 is provided for the main emission edge face of the semiconductor laser elements 10A and 10B, and a high-reflection film 15 is provided for the edge face (rear edge face) on the side opposite to the main emission edge face. The semiconductor laser elements 10A and 10B have a resonator structure in which light emitted from the first and second light emission parts 11 and 12 is resonated between the low-reflection film 14 and the high-reflection film 15. The light resonated by the resonator structure is oscillated as a laser beam from the low-reflection film 14 side to the outside.

Semiconductor Light Emission Part

The first and second light emission parts 11 and 12 are provided while sandwiching an isolation region 13 on a common substrate (not illustrated). The first light emission part 11 has a layer-stack structure formed of, for example, a compound semiconductor such as AlGaInP and has an oscillation wavelength of the 650 nm band (red band). The second light emission part 12 has a layer-stack structure formed of, for example, a compound semiconductor such as AlGaAs and has an oscillation wavelength of the 780 nm band (infrared band). On the top face of each of the first and second light emission parts 11 and 12, for example, a p-side electrode (not illustrated) is provided. On the rear side of the common substrate, for example, an n-side electrode is provided commonly for the first and second light emission parts 11 and 12.

Low-Reflection Film

The low-reflection film 14 is provided commonly for the main emission edge faces of the first and second light emission parts 11 and 12 and is shared by the first and second light emission parts 11 and 12 on the main emission edge face side of the semiconductor laser elements 10A and 10B. The low-reflection film 14 includes, in order from the first and second light emission parts 11 and 12, a first dielectric film 14A, a second dielectric film 14B, and a third dielectric film 14C. It is assumed that the low-reflection film 14 has a three-layer structure, the refractive indexes of the first, second, and third dielectric layers 14A, 14B, and 14C are n1, n2, and n3, respectively. Further, in the low-reflection film 14, the refractive indexes n1, n2, and n3 of the first, second, and third dielectric films 14A, 14B, and 14C satisfy the relation of n3<n1<n2. Consequently, a change in the reflectance in each of the oscillation wavelengths with respect to changes in the optical film thicknesses of the first, second, and third dielectric films 14A, 14B, and 14C becomes mild. That is, to obtain predetermined reflectance in each of the oscillation wavelengths, the physical film thickness of each of the first, second, and third dielectric films 14A, 14B, and 14c may be set in a wide range. Moreover, the reflectance of the low-reflection film 14 at each of the oscillation wavelengths may be easily set in a range of, for example, 25% to 35% both inclusive which is higher than 15%. Therefore, the low-reflectance film 14 may be simultaneously formed with the same thickness on the edge faces on the main emission edge face side of the first and second light emission parts 11 and 12. In each of the multiwavelength semiconductor lasers, even when the physical film thickness of the low-reflectance film 14 varies, since the allowable range of the physical film thickness of the low-reflection film 14 is wide with respect to the reflectance which is set, variations in the laser beam output are suppressed. Further, since the reflectance of the low-reflectance film 14 is easily set in the range of 25% to 35% both inclusive as described above, the multiwavelength semiconductor laser is suitably used as a pickup light source for reproducing a CD/DVD optical recording/reproducing device. The “optical film thickness” is expressed as follows.

Optical film thickness=physical film thickness×refractive index of film

Preferably, the refractive index n1 of the first dielectric film 14A is 1.6 to 1.7 both inclusive, the refractive index n2 of the second dielectric film 14B is 2.0 to 2.3 both inclusive, and the refractive index n3 of the third dielectric film 14C is 1.4 to 1.5 both inclusive for the following reason. In the case of setting the reflectance of the low-reflectance film 14 at each of the oscillation wavelengths to, for example, 25% to 35% both inclusive, the permissible range of the physical film thickness in each of the first, second, and third dielectric films 14A, 14B, and 14C becomes wider. Examples of the materials of the first to third dielectric films 14A, 14B, and 14C having the refractive indexes n1, n2, and n3 are as follows. Examples of the material of the first dielectric film 14A are aluminum oxide (alumina, for example, Al₂O₃: refractive index=1.60 to 1.65) and magnesium oxide (for example, MgO: refractive index=1.7). Each of the materials may be used singularly, or the materials may be mixedly used. Examples of the second dielectric film 14B are tantalum oxide (for example, Ta₂O₅: refractive index=2.1), zirconium oxide (for example, ZrO₂: refractive index=2.00 to 2.05), zinc oxide (for example, ZnO: refractive index=2), hafnium oxide (for example, HfO₂: refractive index=2.2), cerium oxide (for example, CeO₂: refractive index=2.2), niobium oxide (for example, Nb₂O₅: refractive index=2.3), or titanium oxide (for example, TiO₂: refractive index=2.0 or TiO: refractive index=2.2 to 2.3). The material of the third dielectric film 14C is silicon oxide (for example, SiO₂: refractive index=1.46).

Preferably, the first, second, and third dielectric films 14A, 14B, and 14C have a common optical film thickness, that is, the optical film thicknesses of the first, second, and third dielectric films 14A, 14B, and 14C are equal to each other for the reason that the reflectance of the low-reflectance film 14 may be excellently set. In particular, the thickness which is four times as large as that of each of the first to third dielectric films 14A to 14C is preferably 560 nm to 740 nm both inclusive. That is, the optical film thickness of each of the first to third dielectric films 14A to 14C is preferably 140 nm to 185 nm both inclusive. The reflectance in the oscillation wavelength of 650 nm band becomes 25% to 30% both inclusive, and the reflectance in the 780 nm band becomes 25% to 35% both inclusive. The preferred optical film thicknesses of the first to third dielectric films 14A to 14C may have an error of 5% of the optical film thicknesses. In this case as well, a sufficiently excellent effect is obtained.

The reflectance of the low-reflectance film 14 is preferably 25% to 35% in both of the oscillation wavelength of 650 nm band and the 780 nm band. In particular, the reflectance of the low-reflectance film 14 is preferably 25% to 30% in the oscillation wavelength of 650 nm band, and 25% to 35% in the oscillation wavelength of 780 nm band for the reason that the multiwavelength semiconductor laser is suitably used as a pickup light source for reproducing an optical recording/reproducing device. In particular, the reflectance of the low-reflectance film 14 is preferably 25% to 30% both inclusive in the oscillation wavelength 650 nm band, and 30% to 35% both inclusive in the oscillation wavelength 780 nm band for the reason that the multiwavelength semiconductor laser is suitably used as a pickup light source for reproduction.

High-Reflection Film

The high-reflection film 15 is provided commonly for the rear edge faces of the first and second light emission parts 11 and 12 and is shared by the first and second light emission parts 11 and 12 on the rear edge face side of the semiconductor laser elements 10A and 10B. The high-reflection film 15 includes, in order from the first and second light emission parts 11 and 12, a fourth dielectric film 15A and a fifth dielectric film 15B. It is assumed that the high-reflection film 15 has a two-layer structure of the fourth and fifth dielectric layers 15A and 15B. Preferably, the optical film thicknesses of the fourth and fifth dielectric films 15A and 15B are common, that is, equal to each other. In particular, the optical film thickness of the fourth and fifth dielectric films 15A and 15B is preferably the integral multiple (integral multiple of one or larger) of λ/4 (λ denotes oscillation wavelength). The material of the fourth dielectric film 15A is, for example, aluminum oxide. The material of the fifth dielectric film 15B is, for example, amorphous silicon (α-Si).

The reflectance of the high-reflection film 15 is preferably 70% to 80% both inclusive in both of the oscillation wavelength of 650 nm band and the 780 nm band for the reason that the multiwavelength semiconductor laser is suitably used as a pickup light source for reproduction of the optical recording/reproducing device for CD and DVD.

2. Method of Manufacturing Multiwavelength Semiconductor Laser

For example, the multiwavelength semiconductor laser may be manufactured as follows.

First, the first and second light emission parts 11 and 12 are formed on the common substrate while sandwiching the isolation region 13. Concretely, for example, by the MOCVD (Metal Organic Chemical Vapor Deposition) method, an AlGaAs-based compound semiconductor layer whose oscillation wavelength is 780 nm band is formed. After that, on the compound semiconductor layer, by the photolithography process, a mask having a predetermined shape (for example, stripe shape) is formed. Subsequently, selective etching is performed using the mask to expose a part of the common substrate. As a result, the second light emission part 12 is formed. For example, by the MOCVD method, an AlGaInP-based compound semiconductor layer whose oscillation wavelength is 650 nm is formed so as to cover the exposed face of the common substrate and the second light emission part 12. A mask is formed on the compound semiconductor layer by the photolithography process and etching is selectively performed by using the mask. By the process, the first light emission part 11 is formed adjacent to the second light emission part 12 with the isolation region 13 therebetween.

Next, a p-type electrode having a predetermined shape is formed on each of the first and second light emission parts 11 and 12.

The first and second light emission parts 11 and 12 on the common substrate are cleaved and, after that, for example, the low-reflection film 14 is formed on the main emission edge face side. Concretely, on the edge faces of the first and second light emission parts 11 and 12 on the common substrate, the first dielectric film 14A, the second dielectric film 14B, and the third dielectric film 14C are formed in this order.

Next, for example, on the edge face opposite to the edge faces on which the low-reflection film 14 is formed of the first and second light emission parts 11 and 12, the fourth dielectric film 15A and the fifth dielectric film 15B are stacked in this order, thereby forming the high-reflection film 15.

Finally, after the thickness of the common substrate is adjusted by properly polishing the back face, an n-type electrode is formed on the back face of the common substrate. In such a manner, the multiwavelength semiconductor laser illustrated in FIG. 1 is completed.

Action and Effect

In the multiwavelength semiconductor laser, when a predetermined voltage is applied across the n-type electrode and the p-type electrode, light is generated by recombination of electrons and holes in the first and second light emission parts 11 and 12. The light is reflected by the low-reflection film 14 and the high-reflection film 15, laser-oscillates at wavelength in the 650 nm band in the semiconductor laser element 10A and at wavelength in the 780 nm band in the semiconductor laser element 10B, and emits as a laser beam mainly to the outside from the low-reflection film 14 side.

In the multiwavelength semiconductor laser of the embodiment, the low-reflection film 14 commonly provided for the main emission edge faces of the first and second light emission parts 11 and 12 is made of the first, second, and third dielectric films 14A, 14B, and 14C in order from t the first and second light emission parts 11 and 12 side. The refractive indexes n1, n2, and n3 of the first, second, and third dielectric films 14A, 14B, and 14C satisfy the relation of n3<n1<n2. As compared with the case where the low-reflection film 14 is formed by a single dielectric film, the case where the refractive indexes n1, n2, and n3 do not satisfy the relation such as the case where the relation of n1=n3<n2 is satisfied, and the like, changes in the reflectances at the oscillation wavelengths (the 650 nm band and the 780 nm band) with respect to changes in the optical film thicknesses of the first to third dielectric films 14A to 14C become gentler. That is, the permissible range of each of the optical film thicknesses of the first to third dielectric films 14A to 14C, in which the reflectance of the low-reflection film 14 is set to a predetermined value or a predetermined range at different oscillation wavelengths is widened. Moreover, the reflectance of the low-reflection film 14 at each of the oscillation wavelengths may be also easily set to a range higher than 15% such as the range of 25% to 35% both inclusive.

That is, in the multiwavelength semiconductor laser of the embodiment, predetermined reflectance at each of oscillation wavelengths is easily set on the main emission edge face side. In this case, the refractive index n1 of the first dielectric film 14A is set to the range of 1.6≦n1≦1.7. The refractive index n2 of the second dielectric film 14B is set to the range of 2≦n2≦2.3. The refractive index n3 of the third dielectric film 14C is set to the range of 1.4≦n3≦1.5. Accordingly, in the oscillation wavelength of 650 nm band, the reflectance is easily set to the range of 25% to 30% both inclusive. In the oscillation wavelength of 780 nm band, the reflectance is easily set to the range of 25% to 35% b oth inclusive.

In the embodiment, preferably, the first dielectric film 14A is made of the material whose refractive index n1 is set to the range of 1.6≦n1≦1.7. The second dielectric film 14B is made of the material whose refractive index n2 is set to the range of 2≦n2≦2.3. The third dielectric film 14C is made of the material whose refractive index n3 is set to the range of 1.4≦n3≦1.5. In this case, particularly, the first dielectric film 14A is made of at least one of Al₂O₃ and MgO, the second dielectric film is made of at least one of Ta₂O₅, ZrO₂, ZnO, HfO₂, CeO₂, TiO₂, TiO, and Nb₂O₅, and the third dielectric film is made of SiO₂. In such a manner, the reflectance of the low-reflection film 14 which is particularly preferable at the above-described oscillation wavelengths is easily set. When the first, second, and third dielectric films 14A, 14B, and 14C have a common optical film thickness, the reflectance on the main emission edge face side is set more easily.

In the multiwavelength semiconductor laser according to the embodiment as described above, the reflectance in the oscillation wavelength of 650 nm band and the 780 nm band on the main emission edge face side is easily set in the range of 25% to 35% both inclusive. Moreover, the reflectance in the 650 nm band on the main emission edge face is easily set to the range of 25% to 30% both inclusive, and the reflectance in the 780 nm band is easily set to the range of 25% to 35% both inclusive. Consequently, particularly, in the case of using the multiwavelength semiconductor laser to an optical recording/reproducing device for DVD and CD, the multiwavelength semiconductor laser may be excellently used also as a pickup light source for reproduction which is set to an output lower than that of a pickup light source for recording. That is, an optical recording/reproducing device using the multiwavelength semiconductor laser as the light source for reproduction reproduces information excellently for the reason that an output of the light source is set to a suitable range.

### EXAMPLES

Concrete examples of the present invention will be described in detail.

### Experimental Example 1-1

The reflectances at the oscillation wavelengths of the low-reflection film 14 of the multiwavelength semiconductor laser illustrated in FIG. 1 were simulated.

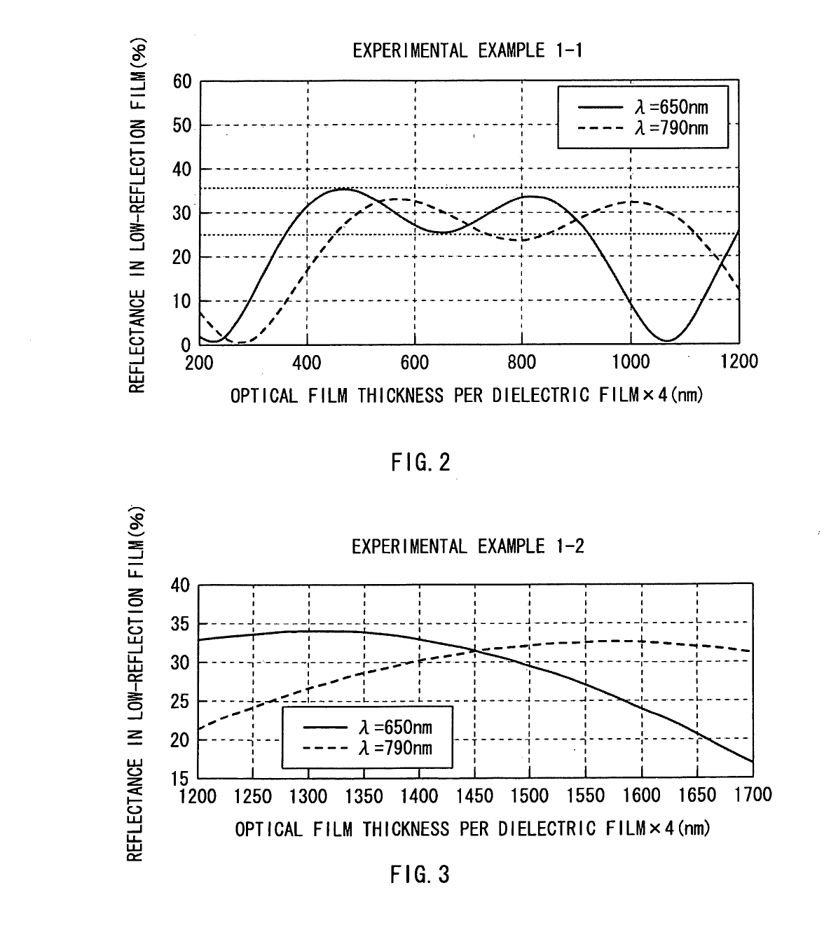

Concrete simulation was set that the low-reflection film 14 was formed by the first dielectric film 14A (Al₂O₃), the second dielectric film 14B (Ta₂O₅), and the third dielectric film 14C (SiO₂) made of the materials illustrated in Table 1. It was assumed that the optical film thicknesses of the first, second, and third dielectric films 14A, 14B, and 14C were equal to each other. The reflectance of the low-reflection film 14 was simulated with respect to changes in the optical film thickness in each dielectric film at the wavelength λ=650 nm and at the wavelength λ=790 nm, and the result illustrated in FIG. 2 was obtained. The reflectance illustrated in FIG. 2 is a value in the case where light having the above-described wavelengths (650 nm and 790 nm) entered from the first dielectric film 14A side of the low-reflection film 14. The horizontal axis in FIG. 2 indicates “optical film thickness×4” (four times of the optical film thickness of each dielectric film) of one of the three dielectric films. That is, the physical film thickness of each dielectric film is calculated as follows.

Physical film thickness of each dielectric film=“value of horizontal axis”/(4×refractive index of each dielectric film)

### Experimental Examples 1-2 to 1-13

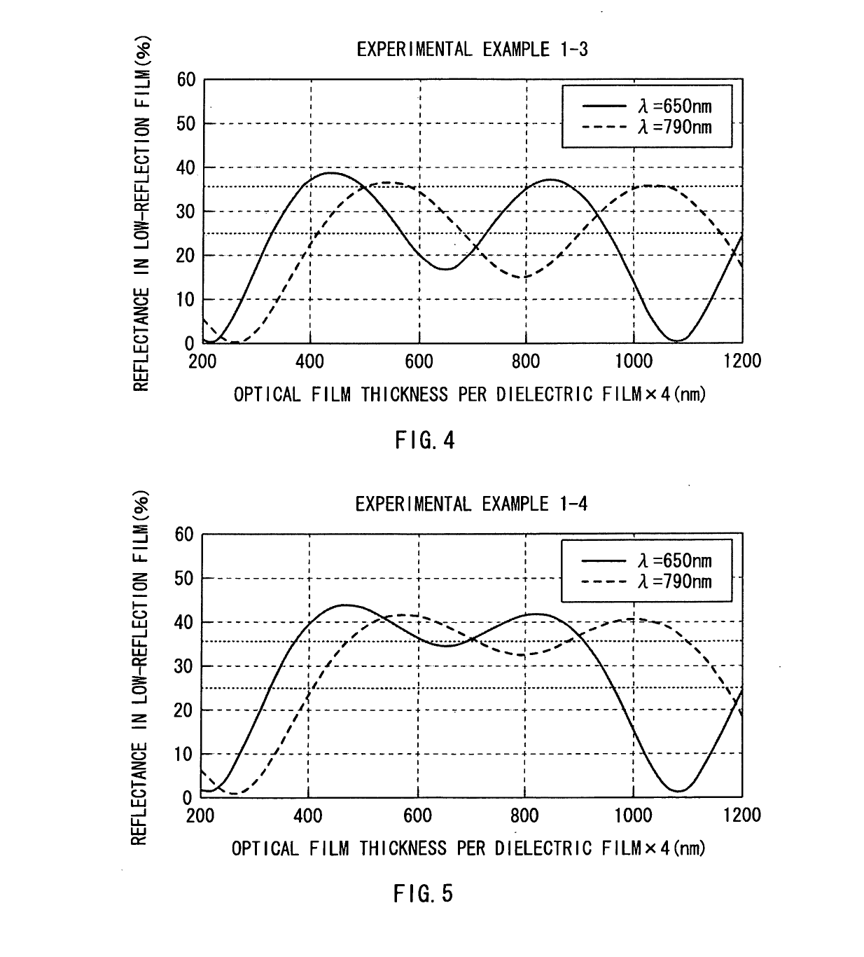

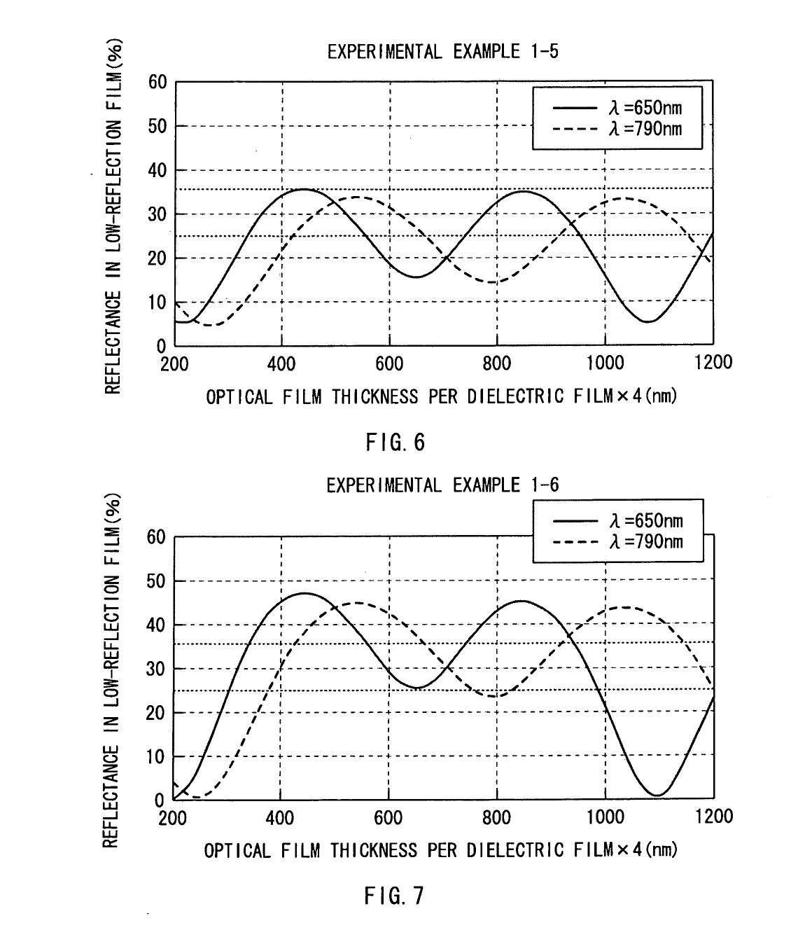

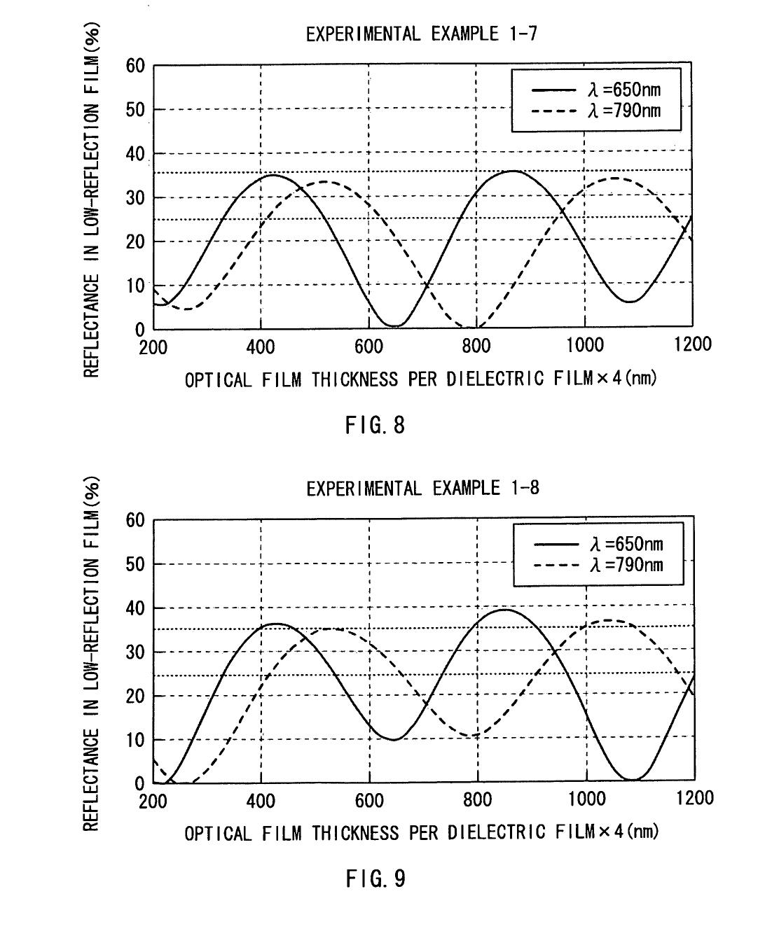

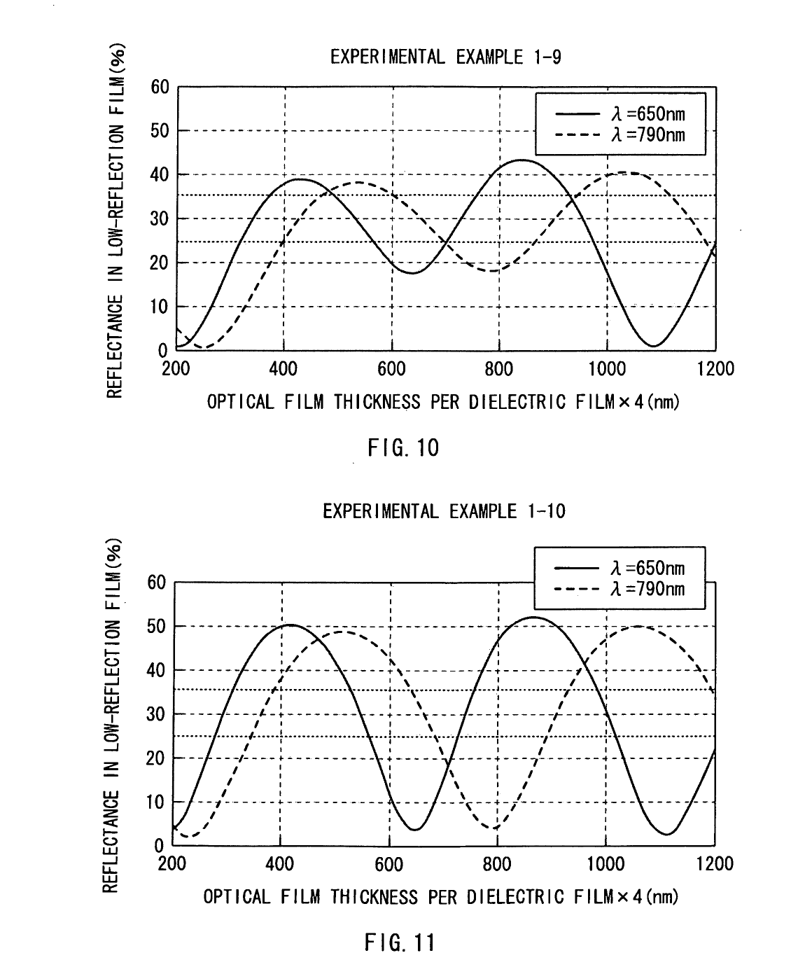

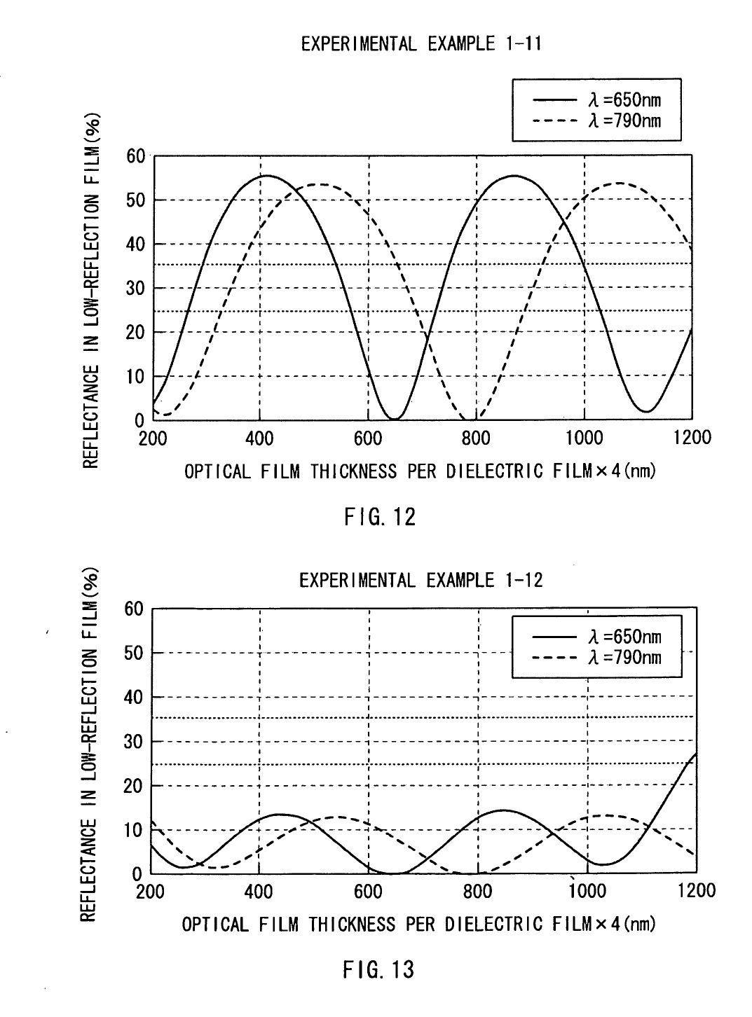

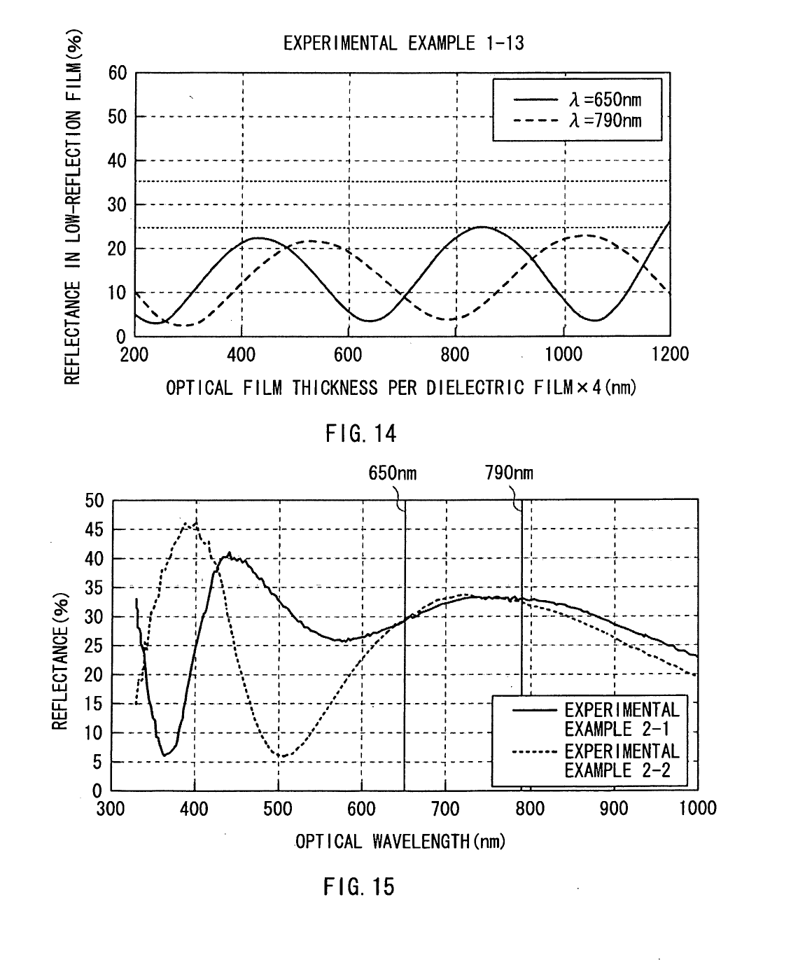

The reflectance was simulated in a manner similar to the experimental example 1-1 except that the materials of the first, second, and third dielectric films 14A, 14B, and 14C were changed as illustrated in Table 1. The results of the experimental examples are illustrated in FIG. 3 (experimental example 1-2), FIG. 4 (experimental example 1-3), FIG. 5 (experimental example 1-4), FIG. 6 (experimental example 1-5), FIG. 7 (experimental example 1-6), FIG. 8 (experimental example 1-7), FIG. 9 (experimental example 1-8), FIG. 10 (experimental example 1-9), FIG. 11 (experimental example 1-10), FIG. 12 (experimental example 1-11), FIG. 13 (experimental example 1-12), and FIG. 14 (experimental example 1-13).

TABLE 1

| | Low-reflection film | | | | |
|---|---|---|---|---|---|
| | First dielectric film | Second dielectric | Third dielectric | Relation | |
| | (refractive index | film (refractive | film (refractive | of n1, n2, | |
| | n1) | index n2) | index n3) | and n3 | Result |
| Experimental | Al₂O₃(1.6 to 1.65) | Ta₂O₅(2.3) | SiO₂(1.45) | n3 < n1 < n2 | FIG. 2 |
| example 1-1 | | | | | |
| Experimental | Al₂O₃(1.6 to 1.65) | — | — | — | FIG. 3 |
| example 1-2 | | | | | |
| Experimental | Al₂O₃(1.6 to 1.65) | Ta₂O₅(2.3) | Al₂O₃(1.6 to 1.65) | n3 = n1 < n2 | FIG. 4 |
| example 1-3 | | | | | |
| Experimental | SiO₂(1.45) | Ta₂O₅(2.3) | SiO₂(1.45) | n3 = n1 < n2 | FIG. 5 |
| example 1-4 | | | | | |
| Experimental | SiO₂(1.45) | Al₂O₃(1.6 to 1.65) | SiO₂(1.45) | n3 = n1 < n2 | FIG. 6 |
| example 1-5 | | | | | |
| Experimental | SiO₂(1.45) | Ta₂O₅(2.3) | Al₂O₃(1.6 to 1.65) | n1 < n3 < n2 | FIG. 7 |
| example 1-6 | | | | | |
| Experimental | Al₂O₃(1.6 to 1.65) | SiO₂(1.45) | Al₂O₃(1.6 to 1.65) | n2 < n1 = n3 | FIG. 8 |
| example 1-7 | | | | | |
| Experimental | Ta₂O₅(2.3) | Al₂O₃(1.6 to 1.65) | Ta₂O₅(2.3) | n2 < n1 = n3 | FIG. 9 |
| example 1-8 | | | | | |
| Experimental | Ta₂O₅(2.3) | SiO₂(1.45) | Ta₂O₅(2.3) | n2 < n1 = n3 | FIG. 10 |
| example 1-9 | | | | | |
| Experimental | Al₂O₃(1.6 to 1.65) | SiO₂(1.45) | Ta₂O₅(2.3) | n2 < n1 < n3 | FIG. 11 |
| example 1-10 | | | | | |
| Experimental | SiO₂(1.45) | Al₂O₃(1.6 to 1.65) | Ta₂O₅(2.3) | n1 < n2 < n3 | FIG. 12 |
| example 1-11 | | | | | |
| Experimental | Ta₂O₅(2.3) | Al₂O₃(1.6 to 1.65) | SiO₂(1.45) | n3 < n2 < n1 | FIG. 13 |
| example 1-12 | | | | | |
| Experimental | Ta₂O₅(2.3) | SiO₂(1.45) | Al₂O₃(1.6 to 1.65) | n2 < n3 < n1 | FIG. 14 |
| example 1-13 | | | | | |

From the results of the reflectance simulations of the experimental examples 1-1 to 1-13, the case of using the multiwavelength semiconductor laser having the low-reflection film of each of the experimental examples as a pickup light source for reproduction of an optical recording/reproducing device for CD and DVD was evaluated. Concretely, the setting range of the reflectance of the low-reflection film was set to the range of 25% to 30% both inclusive at the wavelength of 650 nm and to the range of 25% to 35% both inclusive at the wavelength of 790 nm, and the permissible range of the optical film thickness×4 of one dielectric film (hereinbelow, simply called “optical film thickness permissible range”) was evaluated with respect to the setting ranges.

As illustrated in FIGS. 2 to 14, in the experimental example 1-1 in which the refractive indexes n1, n2, and n3 of the first, second, and third dielectric films 14A, 14B, and 14C satisfy the relation of n3<n1<n2, the optical film thickness permissible range is wider than that of each of the experimental examples 1-2 to 1-13 in which the relation is not satisfied. Concretely, in the experimental example 1-1, the optical film thickness permissible range is about 200 nm. On the other hand, in the experimental example 1-2 in which only one dielectric film made of Al₂O₃ is provided, the optical film thickness permissible range is 100 nm or less. In the experimental examples 1-3 to 1-5 in which the refractive indexes n1, n2, and n3 of the dielectric films satisfy the relation of n3=n1<n2, the optical film thickness permissible range is 50 nm or less or zero. Like the experimental examples 1-3 to 1-5, in the experimental examples 1-6 to 1-13 in which the refractive indexes n1, n2, and n3 of the dielectric films do not satisfy the relation of n3<n1<n2, the optical film thickness permissible range is 50 nm or less or zero.

The results teach the following. In the low-reflection film 14, when the refractive indexes n1, n2, and n3 of the first, second, and third dielectric films 14A, 14B, and 14C satisfy the relation of n3<n1<n2, the reflectance in the oscillation wavelength of 650 nm band is set to the range of 25% to 30% both inclusive, and the -reflectance in the oscillation wavelength of 780 nm band is set to the range of 25% to 35% both inclusive. As compared with the case where the low-reflection film 14 is formed by a single dielectric film, changes in the reflectances with respect to changes in the optical film thickness per film in the first to third dielectric films 14A to 14C become gentler in both of the oscillation wavelength of 650 nm band and 780 nm band. That is, the permissible range of each of the optical film thicknesses of the first to third dielectric films 14A to 14C, in which the reflectance of the low-reflection film 14 is set to a predetermined range at different oscillation wavelengths is widened. Similarly, the permissible range is widened as compared with that in the case where the refractive indexes n1, n2, and n3 of the first, second, and third dielectric films 14A, 14B, and 14C do not satisfy the relation of n3<n1<n2.

### Experimental Example 2-1

The reflectance in the light wavelength range of 400 nm to 1000 nm of the low-reflectance film 14 having a configuration similar to that of the experimental example 1-1 was examined. Concretely, the reflectance of the low-reflectance film 14 at each of the light wavelengths in the case where each of the optical film thicknesses of the first to third dielectric films 14A to 14C×4 was set to 595 nm was calculated. The result is illustrated in FIG. 15.

### Experimental Example 2-2

The reflectances at the light wavelengths of the low-reflection film having a configuration similar to that of the experimental example 2-2 were calculated in a manner similar to the experimental example 2-1. It was assumed that the optical film thickness of the low-reflection film×4 was set to 1,480 nm. The result is also illustrated in FIG. 15.

As illustrated in FIG. 15, in the experimental example 2-1 in which the refractive indexes n1, n2, and n3 of the first, second, and third dielectric films 14A, 14B, and 14C satisfy the relation of n3<n1<n2, variations in the reflectance in the range of the light wavelength 400 nm to 1,000 nm both inclusive were smaller than those in the experimental example 2-2 in which the low-reflectance film is formed by a single dielectric film. That is, in the experimental example 2-1, the amount of change in the reflectance at the light wavelengths is smaller than that in the experimental example 2-2, and the tilt of the reflectance at each of the light wavelengths is smaller.

From the results of FIGS. 2 to 15, in the multiwavelength semiconductor laser, the following was recognized. The low-reflection film 14 shared at the main emission edge face side includes, in order from the first and second light emission parts 11 and 12 side, the first dielectric film 14A, the second dielectric film 14B, and the third dielectric film 14C. The refractive indexes n1, n2, and n3 of the first, second, and third dielectric films 14C, 14B, and 14C satisfy the relation of n3<n1<n2. Consequently, predetermined reflectance at each of the oscillation wavelengths is easily set on the main emission edge face side. In this case, particularly, the reflectance in the oscillation wavelength of 650 nm band and the 780 nm band on the main emission edge face side are easily set to the range of 25% to 35% both inclusive. Moreover, the reflectance in the 650 nm band on the main emission edge face is easily set to the range of 25% to 30% both inclusive. The reflectance in the 780 nm band is easily set in the range of 25% to 35% both inclusive. Therefore, in the case of using the multiwavelength semiconductor laser particularly for an optical recording/reproducing device for DVD and CD, it is excellently used also as the pickup light source for reproduction, which is set to a lower output.

Although the present invention has been described above by the embodiment and the examples, the invention is not limited to the foregoing embodiment and the modes described in the embodiment but may be variously modified. For example, the use application of the multiwavelength semiconductor laser of the invention is not limited to the pickup light source for reproduction in an optical recording/reproducing device but may be other applications. An example of the other applications is a pickup light source for recording in an optical recording/reproducing device.

In the foregoing embodiment, a CD and a DVD have been mentioned as optical recording media which are supported by an optical recording/reproducing device. The optical recording media which are supported by an optical recording/reproducing device are not limited to them but may be other media. Examples of the other optical recording media include a BD (Blu-ray Disc) and HD-DVD.

In the forgoing embodiment and examples, the case where the multiwavelength semiconductor laser is a 2-wavelength semiconductor laser whose oscillation wavelengths are in the 650 nm band and the 780 nm band has been described. However, the multiwavelength semiconductor laser is not limited to the case but may be a 2-wavelength semiconductor laser having other oscillation wavelengths or a multiwavelength semiconductor laser whose oscillation wavelength is three or more wavelengths. Examples of the other oscillation wavelengths include the wavelength of 405 nm band and the wavelength of 850 nm band. Examples of the multiwavelength semiconductor laser having three or more wavelengths include a multiwavelength semiconductor laser having four wavelengths as oscillation wavelengths and a multiwavelength semiconductor laser having three wavelengths as oscillation wavelengths. In this case as well, effects similar to the above are obtained. The “wavelength of 405 nm band” is a wavelength band of 390 nm to 420 nm both inclusive, and the “wavelength of 850 nm band” is a wavelength band of 830 to 870 nm both inclusive.

Further, in the foregoing embodiment and examples, with respect to the refractive indexes of the first to third dielectric films, the optical film thicknesses of the first to third dielectric films, the optical film thicknesses of the low-reflection films, reflectances of the low-reflection films, and the like, proper numerical value ranges are described on the basis of results of the examples and the like. The description does not completely deny the possibility that the refractive indexes of the first to third dielectric films and the like become out of the ranges. The above-described proper ranges are ranges preferable to obtain the effects of the present invention. As long as the effects of the invention are obtained, the refractive indexes of the first to third dielectric films and the like may be slightly out of the above-described ranges.

The present application contains subject matter related to that disclosed in Japanese Priority Patent Application JP 2009-066842 filed in the Japan Patent Office on Mar. 18, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A multiwavelength semiconductor laser comprising:
a plurality of semiconductor light emission parts of an edge emitting type having different oscillation wavelengths; and
a reflection film provided commonly for main emission edge faces of the semiconductor light emission parts,
wherein the reflection film includes, in order from the semiconductor light emission parts, a first dielectric film (refractive index n1), a second dielectric film (refractive index n2), and a third dielectric film (refractive index n3), and
the refractive indexes n1, n2, and n3 satisfy the relation of n3<n1<n2.

2. The multiwavelength semiconductor laser according to claim 1, wherein the refractive index n1 is 1.6 to 1.7 both inclusive, the refractive index n2 is 2 to 2.3 both inclusive, and the refractive index n3 is 1.4 to 1.5 both inclusive.

3. The multiwavelength semiconductor laser according to claim 1, wherein the first dielectric film is made of at least one of Al₂O₃ and MgO, the second dielectric film is made of at least one of Ta₂O₅, ZrO₂, ZnO, HfO₂, CeO₂, TiO₂, TiO, and Nb₂O₅, and the third dielectric film is made of SiO₂.

4. The multiwavelength semiconductor laser according to claim 2, wherein oscillation wavelength of the plurality of semiconductor light emission parts is in either 650 nm band or 780 nm band, and
the reflectance of the reflection film is 25% to 35% both inclusive in any of the oscillation wavelength bands.

5. The multiwavelength semiconductor laser according to claim 4, wherein the first, second, and third dielectric films have a common optical film thickness.

6. The multiwavelength semiconductor laser according to claim 2, wherein the oscillation wavelength of the plurality of semiconductor light emission parts is in either the 650 nm band or the 780 nm band, and
the reflectance of the reflection film is 25% to 30% both inclusive in the oscillation wavelength of 650nm band and is 25% to 35% both inclusive in the oscillation wavelength of 780 nm band.

7. The multiwavelength semiconductor laser according to claim 6, wherein the first, second, and third dielectric films have a common optical film thickness.

8. The multiwavelength semiconductor laser according to claim 3, wherein oscillation wavelength of the plurality of semiconductor light emission parts is in either 650 nm band or 780 nm band, and
the reflectance of the reflection film is 25% to 35% both inclusive in any of the oscillation wavelength bands.

9. The multiwavelength semiconductor laser according to claim 8, wherein the first, second, and third dielectric films have a common optical film thickness.

10. The multiwavelength semiconductor laser according to claim 3, wherein the oscillation wavelength of the plurality of semiconductor light emission parts is in either the 650 nm band or the 780 nm band, and
the reflectance of the reflection film is 25% to 30% both inclusive in the oscillation wavelength of 650 nm band and is 25% to 35% both inclusive in the oscillation wavelength of 780 nm band.

11. The multiwavelength semiconductor laser according to claim 10, wherein the first, second, and third dielectric films have a common optical film thickness.

12. An optical recording/reproducing device comprising a multiwavelength semiconductor laser as a light source for reproduction,
wherein the multiwavelength semiconductor laser includes a plurality of semiconductor light emission parts of an edge emitting type having different oscillation wavelengths, and a reflection film provided commonly for main emission edge faces of the semiconductor light emission parts,
the reflection film has, in order from the semiconductor light emission part side, a first dielectric film (refractive index n1), a second dielectric film (refractive index n2), and a third dielectric film (refractive index n3), and
the refractive indexes n1, n2, and n3 satisfy the relation of n3<n1<n2.
